(19) United States
(12) Patent Application Publication
(10) Pub. No.: US 2018/0197585 A1
(43) Pub. Date: Jul. 12, 2018

(54) CONTROL CIRCUIT FOR A LINE OF A MEMORY ARRAY

(71) Applicant: Dolphin Integration, Meylan (FR)

(72) Inventors: Julien Louche, Grenoble (FR); Olivier Mercier, Echirolles (FR); Khaja Ahmad Shaik, Grenoble (FR)

(73) Assignee: Dolphin Integration, Meylan (FR)

(21) Appl. No.: 15/866,156

(22) Filed: Jan. 9, 2018

(30) Foreign Application Priority Data
Jan. 10, 2017 (FR) 17/50214

(51) Int. Cl. G11C 7/12; G11C 5/14; G11C 7/10

(52) U.S. Cl. CPC G11C 7/12; G11C 7/18; G11C 7/10; G11C 5/147

(57) ABSTRACT

A memory circuit having: a control circuit of a line of a memory array including: a first transistor coupled between first and second nodes and controlled by a line selection signal including a high level and a low level; a second transistor controlled by a first signal and coupled between the first node and a voltage supply rail of a first supply voltage, the first supply voltage being higher than the high level of the line selection signal, the first node being coupled to a line of memory array, the second node receiving a timing signal; and a line deactivation circuit adapted to generate the first signal and including a reference cell and a level shifter.

### FIELD

The present disclosure relates to a memory array and in particular to a control circuit of a line of a memory array.

### BACKGROUND

It is known to drive word lines of a memory array with a voltage that varies between a reference voltage of the memory array, for example a ground voltage, and a voltage CV_{DD} higher than a standard supply voltage V_{DD} of the memory array, in order to improve for example the performance of read and write operations. The line control circuit of the memory array should therefore be adapted to be able to provide a line control signal capable of reaching the voltage level CV_{DD}.

A drawback of line control circuits of this type is that they slow the general operation of the memory array, and/or increase leakage.

### SUMMARY

An aim of an embodiment is to at least partially address drawbacks of existing line control circuits of memory arrays.

A further aim of an embodiment is to enhance the speed of the memory.

According to one aspect, there is provided a memory circuit comprising: a control circuit of a line of a memory array comprising: a first transistor coupled between first and second nodes and controlled by a line selection signal, said line selection signal comprising a high level and a low level; a second transistor controlled by a first signal and coupled between the first node and a voltage supply rail of a first supply voltage, the first supply voltage being higher than the high level of the line selection signal, the first node being coupled to a line of memory array, the second node receiving a timing signal; and a line deactivation circuit adapted to generate the first signal and comprising a level shifter and a reference cell configured to mask the delay of the level shifter.

According to one embodiment, the first node is coupled to the line of the memory array via a latch.

According to one embodiment, the latch comprises a first inverter and a second inverter cross-coupled between the first node and the line of the memory array.

According to one embodiment, the first inverter and the second inverter are supplied by the first supply voltage.

According to one embodiment, the first node is the output node of the first inverter, the first inverter being supplied by the first supply voltage via a third transistor controlled by the output of the second inverter and the first inverter being coupled to a reference voltage rail via a fourth transistor controlled by the first signal.

According to one embodiment, the third transistor is a PMOS transistor and the fourth transistor is an NMOS transistor.

According to one embodiment, the timing signal is a clock signal of the memory circuit.

According to one embodiment, the first transistor is an NMOS transistor and the second transistor is a PMOS transistor.

According to one embodiment, further comprising: a plurality of memory cells arranged in N lines and M columns forming the memory array; N of said line control circuits; said line deactivation circuit common for said N line control circuits; and M column control circuits each controlling a column of memory cells of the memory array and each comprising a supply circuit, a write circuit supplied by a high voltage level and a precharge and keeper circuit supplied by the high voltage level.

According to one embodiment, the supply circuit is adapted to supply each memory cell with the high voltage level during a write operation and with the first supply voltage, higher than the high voltage level, during a read operation.

According to one embodiment, each supply circuit comprises: a seventh transistor coupled between a supply rail at the high voltage level and a third node and controlled by a supply control signal; and an eighth transistor coupled between a supply rail at the first supply voltage and the third node and controlled by the inverse of the supply control signal, the third node being coupled to the memory cells.

According to one embodiment, the at least one reference cell comprises a fifth transistor coupled between a reference bit line and the reference voltage rail and having its control node coupled to the first node.

According to one embodiment, the fifth transistor is coupled to the reference supply rail via a plurality of sixth transistors each controlled by a supply voltage.

### BRIEF DESCRIPTION OF THE DRAWINGS

The foregoing and other features and advantages will become apparent from the following detailed description of embodiments, given by way of illustration and not limitation with reference to the accompanying drawings, in which:

FIGS. 1A and 1B illustrate a control circuit of a line of a memory array;

FIGS. 2A, 2B and 2C illustrate a control circuit of a line of a memory array according to an example embodiment;

FIG. 3 is a timing diagram illustrating signals in the control circuit of FIGS. 2A, 2B and 2C;

FIG. 4 illustrates a memory circuit according to an example embodiment;

FIG. 5 illustrates a reference cell of the memory circuit of FIG. 4 according to an example embodiment; and

FIG. 6 illustrates a column of the memory circuit of FIG. 4 and an associated control circuit according to an example embodiment.

### DETAILED DESCRIPTION

Like elements have been designated with like reference in the various figures.

The term “connected” is used herein to designate a direct connection between two elements, whereas the term “coupled” is used to designate a connection that may be direct, or may be via one or more intermediate elements such as resistors, capacitors, transistors, or latches.

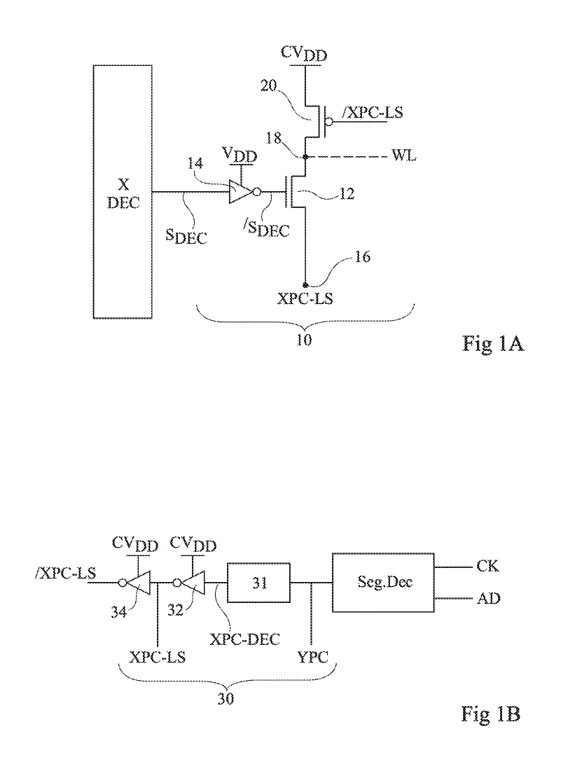

FIGS. 1A and 1B illustrate a line control circuit of a memory array described in more detail in the document “A 0.6V 45 nm adaptive dual-rail SRAM compiler circuit design for lower VDD_min VLSIs”, Y. H. Chen, et al., IEEE Symposium on VLSI Circuits, June 2008, pp. 210-211. This control circuit allows a binary line selection signal WL to be provided for controlling a line of a memory array (not illustrated in FIGS. 1A and 1B) for read and/or write operations. The control circuit comprises a circuit 10, illustrated in FIG. 1A, generating the control signal WL, and a circuit 30, illustrated in FIG. 1B, generating an intermediate binary control signal XPC_LS.

FIG. 1A is a schematic view of the circuit 10. The circuit 10 receives a selection signal S_{DEC} generated by a decoder X DEC based on an address of a memory cell to be selected. The signal S_{DEC} is a binary signal having a high value equal to the supply voltage V_{DD}. The signal S_{DEC} is provided to a control node of an NMOS transistor 12 via an inverter 14. The inverter 14 is supplied by the supply voltage V_{DD}. The transistor 12 is coupled between nodes 16 and 18. The node 16 receives the intermediate control signal XPC_LS. The node 18 provides the control signal WL. A PMOS transistor 20 is coupled between the node 18 and a supply rail of the supply voltage CV_{DD}. The transistor 20 is controlled by the inverse signal /XPC_LS of the signal XPC_LS. The supply voltage CV_{DD} is higher than the supply voltage V_{DD}.

FIG. 1B is a schematic view of the circuit 30. The circuit 30 receives a signal XPC generated by a line decoder Seg.Dec. The decoder Seg.Dec generates the signal XPC based on a clock signal CK of a memory circuit comprising the memory array, and on an address signal AD. The decoder Seg.Dec allows the selection of a memory segment based on part of the address signal AD. The signal XPC is a binary signal having a high level equal to the supply voltage V_{DD}. The signal XPC is transmitted to a level shifter 31, which provides a level-shifted voltage signal XPC_DEC having a high value equal to the supply voltage CV_{DD}. The signal XPC_DEC is then provided to an inverter 32, supplied by the supply voltage CV_{DD}, generating the intermediate control signal XPC_LS. The intermediate control signal XPC_LS is then inverted by an inverter 34, supplied by the supply voltage CV_{DD}, in order to generate the inverted intermediate control signal /XPC_LS.

When a line of the memory array coupled to circuit 10 is selected, the line selection signal S_{DEC} changes level. The signal XPC_LS permits the signal WL to transition from a low level to a high level and the signal /XPC_LS permits the signal WL to transition from a high level to a low level.

A drawback of this line control circuit is that the signal XPC_LS is generated based on a clock signal CK via a level shifter. The level shifter introduces a delay between the clock signal CK and the signal XPC_LS.

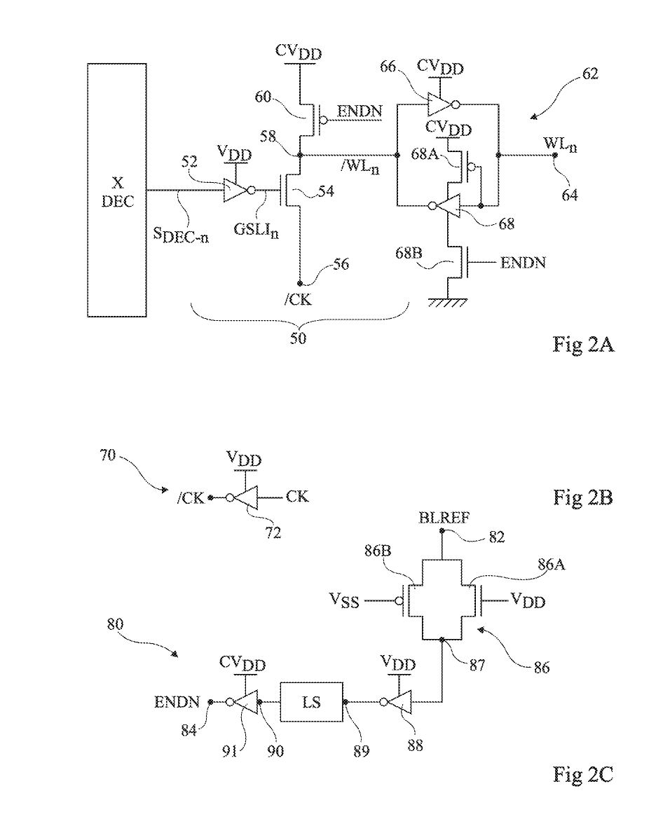

FIGS. 2A, 2B and 2C illustrate an embodiment of a control circuit of a line of a memory array. This control circuit allows a control signal WLₙ to be provided which selects a line of index n of the memory array, for example for read or write operations, where n is an integer between 1 and N, and N is the number of lines of the memory array, for example equal to between 2 and several thousand. The control circuit comprises a line control circuit 50 generating the control signal WLₙ, a circuit 70 generating a clock signal /CK and a line deactivation circuit 80 generating an intermediate control signal ENDN.

FIG. 2A is a schematic view of the circuit 50. The circuit 50 receives a selection signal S_{DEC-n} of a decoder X DEC. The signal S_{DEC-n} is a binary signal having a high level equal to the supply voltage V_{DD}. The signal S_{DEc-n} is for example provided to an inverter 52, supplied by the supply voltage V_{DD}, which provides a signal GSLIₙ, this signal being the signal S_{DEC-n} inverted. This signal GSLIₙ controls a transistor 54. The transistor 54 is coupled between nodes 56 and 58. The transistor 54 is for example an NMOS transistor. The node 56 receives the clock signal /CK. The node 58 provides an inverted signal /WLₙ of the control signal WLₙ. The circuit 50 for example further comprises a transistor 60 coupled between the node 58 and a supply rail of the supply voltage CV_{DD}. The supply voltage CV_{DD} is for example higher than the supply voltage V_{DD}. The difference between CV_{DD} and V_{DD} is for example around 0.2 V. The transistor 60 is controlled by the intermediate control signal ENDN. The transistor 60 is for example a PMOS transistor.

The circuit 50 further comprises a latch 62 coupled between the node 58 and an output node 64 of the circuit 50. The output node 64 transmits the line control signal WLₙ. The latch 62 for example comprises two inverters 66 and 68, each supplied by the supply voltage CV_{DD}, and for example cross-coupled between the node 58 and the output node 64. In particular, the inverter 68 is for example supplied by the supply voltage CV_{DD} via a transistor 68A and is for example coupled to a reference supply rail, for example ground, via a transistor 68B. The transistor 68A is for example controlled by the output node 64 and is for example an PMOS transistor. The transistor 68B is for example controlled by the signal ENDN and is for example a NMOS transistor.

FIG. 2B is a schematic view of the circuit 70 generating the clock signal /CK. The circuit 70 for example comprises an inverter 72, supplied by the supply voltage V_{DD}. The inverter 70 receives for example the clock signal CK of the memory array and provides the inverted clock signal /CK.

FIG. 2C is a schematic view of the line deactivation circuit 80 generating the intermediate control signal ENDN. The circuit 80 for example comprises, between an input node 82 and an output node 84, the following elements successively coupled in series:

a switch 86 comprising for example an NMOS transistor 86A and a PMOS transistor 86B, the transistors 86A and 86B being connected in parallel via their main connecting nodes between the input node 82 and a node 87;

an inverter 88 supplied by the supplied voltage V_{DD}, and coupled between the node 87 and a node 89;

a level shifter LS allowing the high level of the signal from inverter 88 to be increased from the supply voltage V_{DD} to the supply voltage CV_{DD}, and coupled between the node 89 and the node 90; and

an inverter 91 supplied by the supply voltage CV_{DD} and coupled between the node 90 and the output node 84.

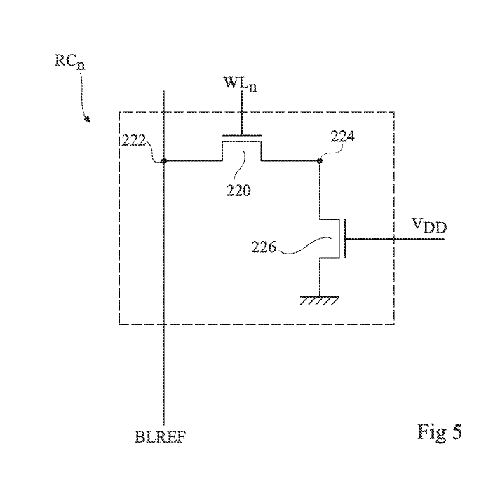

The input node 82 receives a reference signal BLREF generated by a column REFCOL of reference cells. A reference cell is a circuit permitting the discharge time of the bit lines of the memory array to be evaluated. A reference cell will be described in more detail below in relation with FIG. 5. The switch 86 is for example always ON, the transistor 86A being controlled by the supply voltage V_{DD} and the transistor 86B being controlled by a reference voltage V_{SS}. The presence of the switch allows the signal BLREF to be generated under the same conditions as the signals generated by the columns of the memory array.

The level shifter may for example comprise a plurality of inverters and/or buffers supplied by voltages that are progressively higher from one to the next.

The circuit 80 provides at its node 84 the intermediate control signal ENDN.

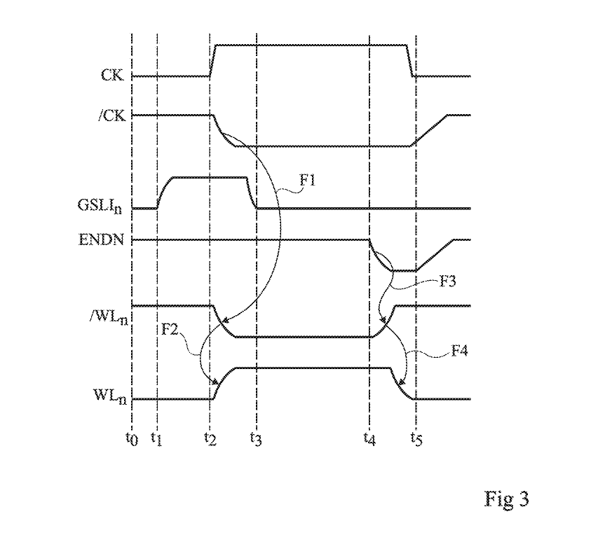

FIG. 3 is a timing diagram illustrating the timing of signals CK, /CK, GSLIₙ, ENDN, /WLₙ and WLₙ of the circuits 50, 70 and 80 presented in relation with FIGS. 2A, 2B and 2C, for a line of index n, according to an example.

At a time instant t₀, the line of index n of the memory array is for example not selected. The line selection signal GSLIₙ is therefore at a low level. The clock signal CK is at a low level and the inverted clock signal /CK is at a high level. The intermediate control signal ENDN and the inverted control signal /WLₙ are for example at a high level. The control signal WLₙ is at a low level.

At a time instant t₁, the signal GSLIₙ transitions for example to a high level in order to select the line n.

At a time instant t₂, a rising edge of the clock signal CK causes the signal /WLₙ to fall from a high level to a low level, as represented in FIG. 3 by an arrow F1. The control signal WLₙ thus transitions from a low level to a high level, as represented in FIG. 3 by an arrow F2, and the line n is selected.

At a time instant t₃, the line selection signal GSLIₙ transitions for example from a high level to a low level.

At a time instant t₄, the intermediate control signal ENDN transitions from a high level to a low level, which causes the signal /WLₙ to rise from a low level to a high level, represented in FIG. 3 by an arrow F3. The control signal WLₙ thus transitions from a high level to a low level, represented in FIG. 3 by an arrow F4, and the line n is no longer selected. The duration between the time instant t2 and the falling edge of the signal WLₙ is controlled based on an approximation of the discharge time of a bit line during a read phase of a memory cell.

At a time instant t₅, the signal ENDN for example transitions from a low level to a high level. Indeed, the transition of the signal WLₙ from a high level to a low level causes the signal BLREF transition from a low level to a high level, which in turn causes the signal ENDN to transition.

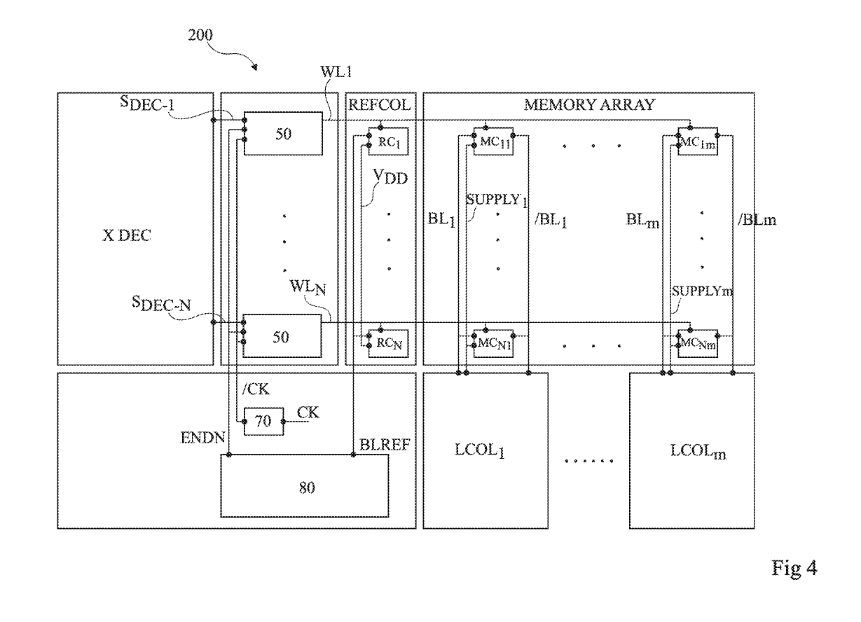

FIG. 4 is a schematic view of a memory circuit 200. The memory circuit 200 comprises:

a plurality of memory cells MC₁₁, . . . , MC_{NM} arranged in a memory array (MEMORY ARRAY) of N lines and M columns, M being an integer of for example between 2 and several thousand;

a column REFCOL comprising for example N reference cells RC₁, . . . , RC_{N}, generating the reference signal BLREF;

N line control circuits 50 of the same type as that described in relation with FIG. 2A;

a decoder X DEC having N outputs, each output supplying, to a line control circuit 50, a line selection signal S_{DEC-1}, . . . , S_{DEC-N};

a circuit 70 generating the clock signal /CK of the same type as that described in relation with FIG. 2B;

a circuit 80 generating the intermediate control signal ENDN based on the signal BLREF, of the same type as that described in relation with FIG. 2B; and

M control circuits LCOL₁ to LCOL_{M}.

Each memory circuit MCₙ₁, . . . , MC_{nM} of a same line of index n of the memory array receives a control signal WLₙ from one of the control circuits 50. Each control signal WL₁, . . . , WL_{N} is also received by a reference cell RC₁, . . . , RC_{N} of the reference column REFCOL.

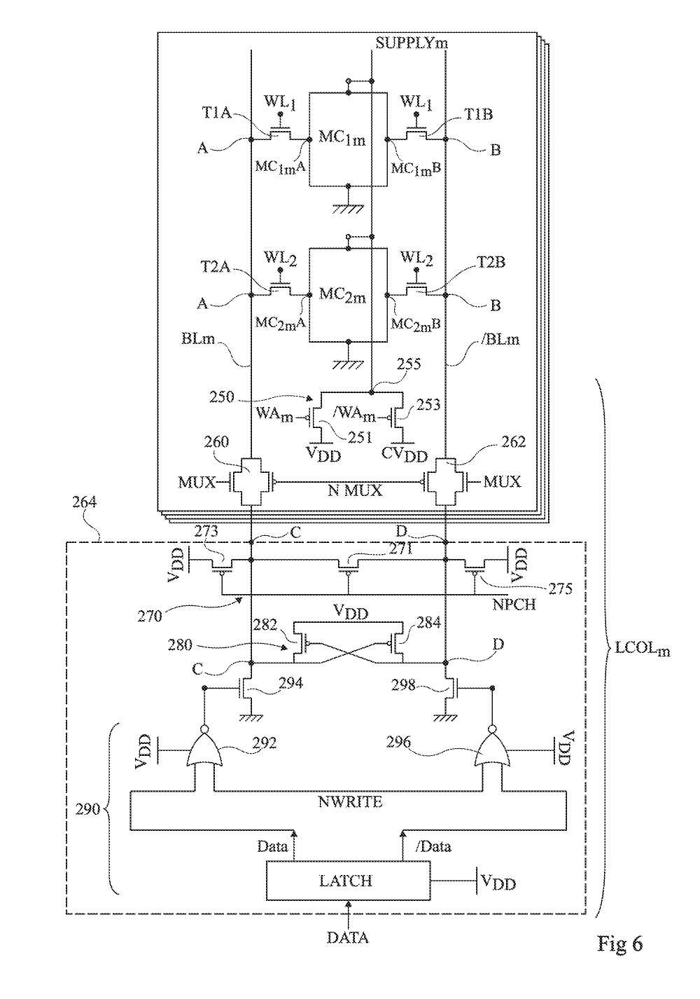

Each memory cell MC₁ₘ, . . . , MC_{Nm} of a same column indexed m of the memory array is connected to two bit lines BLₘ and /BLₘ and to a variable supply voltage SUPPLYₘ. Each column of the memory array is coupled to a circuit LCOL₁, . . . , LCOL_{M} permitting the memory cells of the column to be powered, read and written. These circuits will be described in relation with FIG. 6.

Each reference cell RC₁, . . . , RC_{N} is connected to a reference bit line and is supplied by the supply voltage V_{DD}.

During a read operation of a memory cell MCₙₘ of a line of index n and of a column of index m, the address of the memory cell MCₙₘ is decoded by the decoder X DEC. The decoder X DEC supplies a signal S_{DEC-n} to the line of index n. The line selection signal S_{DEC-n} is supplied to the line control circuit 50. The signals /CK and ENDN are supplied to the line control circuits 50 after having been generated by the respective circuits 70 and 80, as described in relation with FIGS. 2A, 2B and 2C. The circuit 80 receives the reference signal BLREF transmitted by the reference bit line, which sets the duration between two operations, and allows this duration to be reduced. Indeed, the reference bit line permits the signal ENDN to be generated, the role of this signal being to cause the line control signal WLₙ to fall from a high level to a low level.

FIG. 5 is a schematic view of a reference cell RCₙ coupled to a line of index n, according to an example embodiment. The reference cell RCₙ for example comprises an NMOS transistor 220, coupled between nodes 222 and 224. The transistor 220 is controlled by the line control signal WLₙ. The reference cell RCₙ for example further comprises a NMOS transistor 226 coupled between the node 224 and a reference supply voltage, for example ground. The transistor 226 is controlled by the supply voltage V_{DD}. The node 222 is coupled to the reference bit line on which is transmitted the reference signal BLREF.

During a read operation, the reference bit line is for example pre-charged and the reference cells RC₁, . . . , RC_{N} are supplied by the supply voltage V_{DD}. When a line of the memory array is selected by the signal S_{DEC-n} and then controlled by the signal WLₙ, the signal of the reference bit line falls from a high level to a low level. The intermediate control signal is then generated by the circuit 80 with a certain time delay, and causes the signal WLₙ to fall from a high level to a low level. This operation has the same duration as that of the discharge of the bit lines BL₁, . . . , BL_{M} of the memory array. The duration between two read operations is thus reduced by the delay between the signal BLREF and the signal ENDN. In some embodiments, it is possible to mask the delay introduced by the level shifter by reducing the delay introduced by the reference cell. For example, this is achieved by adding transistors, for example NMOS transistors, in parallel with the transistors 226, between the reference supply rail and the node 224.

FIG. 6 a schematic view of a column of index m of memory cells and of a control circuit LCOLₘ. As an example, in FIG. 6, the column comprises two memory cells MC₁ₘ and MC₂ₘ. Each memory cell MC₁ₘ, MC₂ₘ is supplied by a variable supply voltage SUPPLYₘ.

The memory cell MC₁ₘ comprises two storage nodes MC₁ₘA and MC₁ₘB. The storage node MC₁ₘA is coupled to the bit line BLₘ of the column m via a transistor T1A. The transistor T1A is controlled by a line control signal WL₁. The storage node MC₁ₘB is coupled to a bit line /BLₘ via a transistor T1B. The transistor T1B is controlled by the control signal WL₁.

The memory cell MC₂ₘ comprises two storage nodes MC₂ₘA and MC₂ₘB. The storage node MC₂ₘA is coupled to the bit line BLₘ of the column m, via a transistor T2A. The transistor T2A is controlled by a line control signal WL₂. The storage node MC₂ₘB is coupled to the bit line /BLₘ via a transistor T2B. The transistor T2B is controlled by the line control signal WL₂.

The control circuit LCOLₘ comprises a supply circuit 250 comprising two transistors 251 and 253, which are for example PMOS transistors. The transistor 251 is coupled between a supply rail of the supply voltage V_{DD} and an output node 255 of the supply circuit, and is controlled by a supply voltage control signal WAₘ. The transistor 253 is coupled between a supply rail of the supply voltage CV_{DD} and the output node 255 of the supply circuit. The transistor 251 is controlled by the inverted supply voltage control signal /WAₘ. The node 255 provides the variable supply voltage SUPPLYₘ. During a read operation, the signal WAₘ is at a high level, and thus the variable supply voltage SUPPLYₘ is equal to the supply voltage CV_{DD}. During a write operation, the signal WAₘ is at a low level, and thus the variable supply voltage SUPPLYₘ is equal to the supply voltage V_{DD}.

The control circuit LCOLₘ further comprises a switch 260 coupling the bit line BL₁ to a node C and a switch 262 coupling the bit line /BL₁ to a node D. Each switch 260, 262 is for example formed of two transistors coupled in parallel, one being an NMOS transistor and the other being a PMOS transistor. The NMOS transistors of the switches 260, 262 are controlled by a signal MUX, and the PMOS transistors of the switches 260, 262 are controlled by the inverse NMUX of the signal MUX. For example, as this is represented in FIG. 6, each column may comprises several pairs of bit lines and corresponding memory cells. Switches 260 and 262, and similar switches for the other pairs of bit lines, allows the selection of one of the pairs of bit lines to be coupled to a read/write circuit 264 forming part of the control circuit LCOLₘ. The read/write circuit 264 is shared between all the pairs of bit lines of the same column. In this case, each pair of bit lines is supplied by its own supply circuit 250.

In other embodiments, there could be only one pair of bit lines, in which case the switches 260 and 262 could be omitted.

The read/write circuit 264 further comprises a pre-charge circuit 270 for pre-charging the bit lines and comprising a transistor 271, for example a PMOS transistor, coupled between the nodes C and D, a transistor 273, for example a PMOS transistor, coupled between the node C and a supply rail of the supply voltage V_{DD} and a transistor 275, for example a PMOS transistor, coupled between the node D and a supply rail of the supply voltage V_{DD}. The transistors 271, 273 and 275 are controlled by a pre-charge signal NPCH.

The read/write circuit 264 further comprises a precharge and keeper circuit 280 comprising two transistors 282 and 284, for example PMOS transistors. The transistor 282 is coupled between the node C and a supply rail of the supply voltage V_{DD} and its control node is coupled to the node D. The transistors 284 is coupled between the node D and a supply rail of the supply voltage V_{DD}, and its control node is coupled to the node C.

The read/write circuit 264 further comprises a write circuit 290 for writing data Data to a selected memory cell. A signal comprising the data Data to be written is provided to a latch (LATCH) supplied by the supply voltage V_{DD}. The latch provides at its output a signal comprising the data Data and at a further output a signal comprising the inverse /Data of the data Data. A NOR gate 292, supplied by the supply voltage V_{DD}, receives on one input the data signal Data and on another input a write control signal NWRITE. The output of the logic gate 292 controls the transistor 294, which is for example an NMOS transistor, coupled between the reference voltage supply rail, for example ground, and the node C. A NOR gate 296, supplied by the supply voltage V_{DD}, receives at one input the data Data and on another input the write control signal NWRITE. The output of the logic gate 296 controls a transistor 298, which is for example an NMOS transistor, coupled between the reference supply voltage rail, for example ground, and the node D. The signal NWRITE is a signal permitting the data Data and /Data received by the NOR gates 292 and 296 to be written to the bit lines BLₘ and /BLₘ.

An advantage of the line control circuit described herein is that the activation of the word lines is achieved by a timing signal /CK, which is directly generated based on a timing signal CK of the memory array, in other words without passing through a level shifter. The deactivation of the word lines on the other hand is implemented by a signal ENDN that is auto-synchronized by reference cells and generated by a circuit comprising a level shifter. The time delay introduced by the level shifter can be masked by reducing the delay of the reference cells.

Having thus described at least one illustrative embodiment, various alterations, modifications and improvements will readily occur to those skilled in the art. In particular, it will be clear to those skilled in the art that it would be possible to replace the NMOS transistors by PMOS transistors and to replace the PMOS transistors by NMOS transistors.

Furthermore, alternative transistor technologies could be used to replace the NMOS and PMOS transistors, for example bipolar transistors.

Various embodiments having a range of alternatives have been described herein. Those skilled in the art will appreciate that the various elements of the various embodiments can be combined in any combination in an obvious manner.

1. A memory circuit comprising:
a control circuit of a line of a memory array comprising:
a first transistor coupled between first and second nodes and controlled by a line selection signal, said line selection signal comprising a high level and a low level;
a second transistor controlled by a first signal and coupled between the first node and a voltage supply rail of a first supply voltage, the first supply voltage being higher than the high level of the line selection signal, the first node being coupled to a line of memory array, the second node receiving a timing signal; and
a line deactivation circuit adapted to generate the first signal and comprising a level shifter and a reference cell ERG configured to mask the delay of the level shifter.

2. The circuit of claim 1, wherein the first node is coupled to the line of the memory array via a latch.

3. The circuit of claim 2, wherein the latch comprises a first inverter and a second inverter cross-coupled between the first node and the line of the memory array.

4. The circuit of claim 3, wherein the first inverter and the second inverter are supplied by the first supply voltage.

5. The circuit of claim 4, wherein the first node is the output node of the first inverter, the first inverter being supplied by the first supply voltage via a third transistor controlled by the output of the second inverter and the first inverter being coupled to a reference voltage rail via a fourth transistor controlled by the first signal.

6. The circuit of claim 5, wherein the third transistor is a PMOS transistor and the fourth transistor is an NMOS transistor.

7. The circuit of claim 1, wherein the timing signal is a clock signal of the memory circuit.

8. The circuit of claim 1, wherein the first transistor is an NMOS transistor and the second transistor is a PMOS transistor.

9. The circuit of claim 1, further comprising:
a plurality of memory cells arranged in N lines and M columns forming the memory array;
N of said line control circuits;
said line deactivation circuit common for said N line control circuits; and
M column control circuits each controlling a column of memory cells of the memory array and each comprising a supply circuit, a write circuit supplied by a high voltage level and a precharge and keeper circuit supplied by the high voltage level.

10. The circuit of claim 9, wherein the supply circuit is adapted to supply each memory cell with the high voltage level during a write operation and with the first supply voltage, higher than the high voltage level, during a read operation.

11. The circuit of claim 10, wherein each supply circuit comprises:
a seventh transistor coupled between a supply rail at the high voltage level and a third node and controlled by a supply control signal; and
an eighth transistor coupled between a supply rail at the first supply voltage and the third node and controlled by the inverse of the supply control signal, the third node being coupled to the memory cells.

12. The circuit of claim 9, wherein the at least one reference cell comprises a fifth transistor coupled between a reference bit line and the reference voltage rail and having its control node coupled to the first node.

13. The circuit of claim 12, wherein the fifth transistor is coupled to the reference supply rail via a plurality of sixth transistors each controlled by a supply voltage.
